(19) United States
(12) Patent Application Publication
(10) Pub. No.: US 2011/0201202 A1
(43) Pub. Date: Aug. 18, 2011

(54) METHOD OF FORMING FINE PATTERNS OF SEMICONDUCTOR DEVICE

(76) Inventors: Chong-Kwang CHANG, Bupyeong-gu (KR); Young-Mook OH, Hwaseong-si (KR); Seo-Woo NAM, Yongin-si (KR); Woo-Cheol JEON, Bucheon-si (KR); Ju-Beom YI, Suwon-si (KR); Myung-Joo LEE, Seoul (KR)

(21) Appl. No.: 13/007,071

(22) Filed: Jan. 14, 2011

(30) Foreign Application Priority Data
Feb. 12, 2010 (KR) 10-2010-0013582

(51) Int. Cl. H01L 21/3105

(52) U.S. Cl. 438/699; 257/E21.243

(57) ABSTRACT

A method of forming fine patterns of a semiconductor device, the method including providing a patternable layer; forming a plurality of first photoresist layer patterns on the patternable layer; forming an interfacial layer on the patternable layer and the plurality of first photoresist layer patterns; forming a planarization layer on the interfacial layer; forming a plurality of second photoresist layer patterns on the planarization layer; forming a plurality of planarization layer patterns using the plurality of second photoresist layer patterns; and forming a plurality of layer patterns using the plurality of planarization layer patterns and the plurality of first photoresist layer patterns.

### BACKGROUND

1. Field

Embodiments relate to a method of forming fine patterns of a semiconductor device.

2. Description of the Related Art

As semiconductor devices become smaller, demand for semiconductor devices having fine patterns has continuously increased. However, patterning of a semiconductor device using photolithography has a limitation in the resolution of an exposure apparatus. Accordingly, it may be quite difficult to realize formation of finer patterns.

### SUMMARY

Embodiments are directed to a method of forming fine patterns of a semiconductor device.

At least one of the above and other features and advantages may be realized by providing a method of forming fine patterns of a semiconductor device, the method including providing a patternable layer; forming a plurality of first photoresist layer patterns on the patternable layer; forming an interfacial layer on the patternable layer and the plurality of first photoresist layer patterns; forming a planarization layer on the interfacial layer; forming a plurality of second photoresist layer patterns on the planarization layer; forming a plurality of planarization layer patterns using the plurality of second photoresist layer patterns; and forming a plurality of layer patterns using the plurality of planarization layer patterns and the plurality of first photoresist layer patterns.

Forming the interfacial layer may include conformally forming the interfacial layer on the patternable layer and the plurality of first photoresist layer patterns.

Conformally forming the interfacial layer may include ALD (Atomic Layer Deposition) or LTO (Low Temperature Oxide) deposition.

The interfacial layer may have a thickness of about 5 to about 50 Å.

The interfacial layer may include at least one of a silicon film, an oxide film, a nitride film, a metal film, and combinations thereof.

The planarization layer may include an organic material.

The organic material may include at least one of SOH, SO, and NFC.

Forming the planarization layer on the interfacial layer may include forming the planarization layer such that a height from a top surface of the patternable layer to a top surface of the planarization layer is greater than a height from the top surface of the patternable layer to a top surface of portions of the interfacial layer on the first photoresist layer patterns.

An interval between adjacent first photoresist layer patterns may be about equal to an interval between adjacent second photoresist layer patterns.

An interval between one of the planarization layer patterns and an adjacent first photoresist layer pattern may be smaller than the interval between the adjacent first photoresist layer patterns or smaller than the interval between the adjacent second photoresist layer patterns.

Forming the plurality of planarization layer patterns using the plurality of second photoresist layer patterns may include etching the planarization layer using the plurality of second photoresist layer patterns as etch masks.

Forming the plurality of layer patterns using the plurality of planarization layer patterns and the plurality of first photoresist layer patterns may include etching the patternable layer using the plurality of planarization layer patterns and the plurality of first photoresist layer patterns as etch masks.

At least one of the above and other features and advantages may also be realized by providing a method of forming fine patterns of a semiconductor device, the method including forming a cavity having a bottom and side walls such that the bottom is formed by an underlying material and the side walls are formed by even-numbered column etch masks; forming an anti-reactive layer in the cavity and on surfaces of the even-numbered column etch masks; filling the cavity having the anti-reactive layer therein with an odd-numbered column etch mask layer; forming auxiliary masks on the odd-numbered column etch mask layer; forming odd-numbered column etch masks by etching the odd-numbered column etch mask layer using the auxiliary masks; and etching the underlying material using the even- and odd-numbered etch masks.

The anti-reactive layer may prevent the even-numbered column etch masks from being etched during forming of the odd-numbered etch masks.

Forming the anti-reactive layer may include conformally forming the anti-reactive layer in the cavity and on the surfaces of the even-numbered column etch masks.

The anti-reactive layer may have a thickness of about 5 to about 50 Å.

The anti-reactive layer may include at least one of a silicon film, an oxide film, a nitride film, a metal film, and combinations thereof.

The odd-numbered etch masks may include an organic material, the organic material including at least one of SOH, SO, and NFC.

Filling the cavity with an odd-numbered column etch mask layer may include forming the odd-numbered column etch mask layer such that a height from the bottom of the cavity to a top surface of the odd-numbered column etch mask layer is about equal to a height from the bottom of the cavity to a top surface of portions of the anti-reactive layer on the even-numbered column etch masks.

At least one of the above and other features and advantages may also be realized by providing a method for forming fine patterns of a semiconductor device, the method including providing a patternable layer; forming a plurality of first photoresist layer patterns on the patternable layer; conformally forming an interfacial layer having a thickness of about 5 to about 50 Å on the patternable layer and on the plurality of first photoresist layer patterns using ALD (Atomic Layer Deposition) or LTO (Low Temperature Oxide) deposition; forming a planarization layer on the interfacial layer such that the planarization layer includes an organic material including at least one of SOH, SO, and NFC; forming a plurality of second photoresist layer patterns on the planarization layer; forming a plurality of planarization layer patterns by etching the planarization layer using the plurality of second photoresist layer patterns as etch masks; and forming a plurality of layer patterns by etching the patternable layer using the plurality of planarization layer patterns and the plurality of first photoresist layer patterns as etch masks.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a flowchart of a method of forming fine patterns of a semiconductor device according to an embodiment;

FIGS. 2 through 7 illustrate cross-sectional views of stages in the method of forming fine patterns of a semiconductor device according to an embodiment; and

FIGS. 8 and 9 illustrate cross-sectional views of stages in a method of forming fine patterns of a semiconductor device according to another embodiment.

### DETAILED DESCRIPTION

Korean Patent Application No. 10-2010-0013582, filed on Feb. 12, 2010, in the Korean Intellectual Property Office, and entitled: “Method for Forming Fine Patterns of Semiconductor Device,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

As used herein, the term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that, although the terms first, second, etc. may be used herein to describe various elements, these elements should not be limited by these terms. These teems are only used to distinguish one element from another element. Thus, for example, a first element, a first component or a first section discussed below could be termed a second element, a second component or a second section without departing from the teachings of the present invention.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the embodiments.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

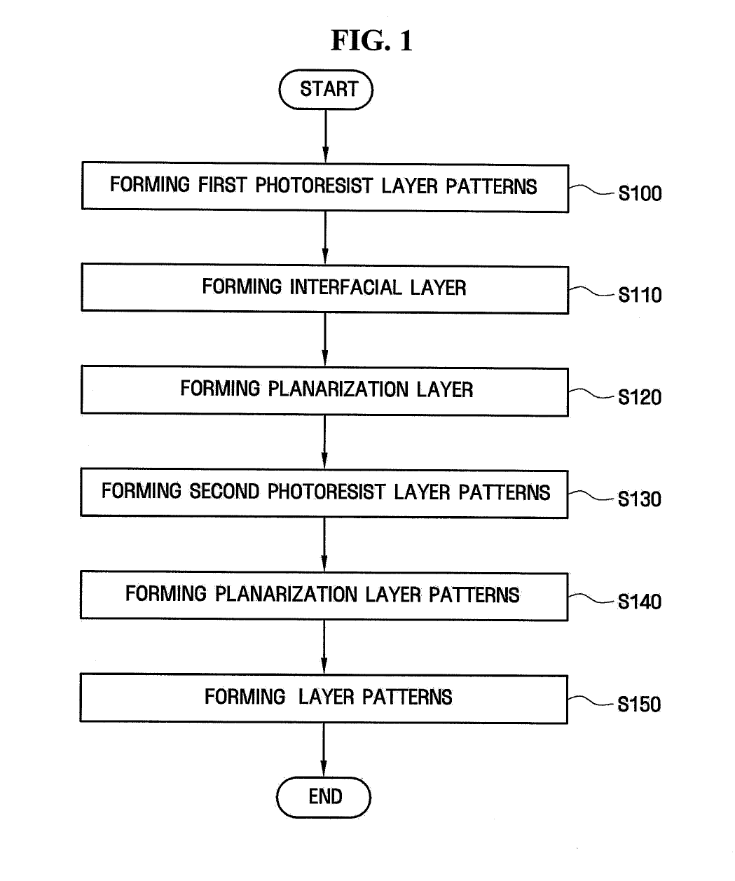

Hereinafter, a method of forming fine patterns of a semiconductor device according to an embodiment will be described with reference to FIGS. 1 through 7.

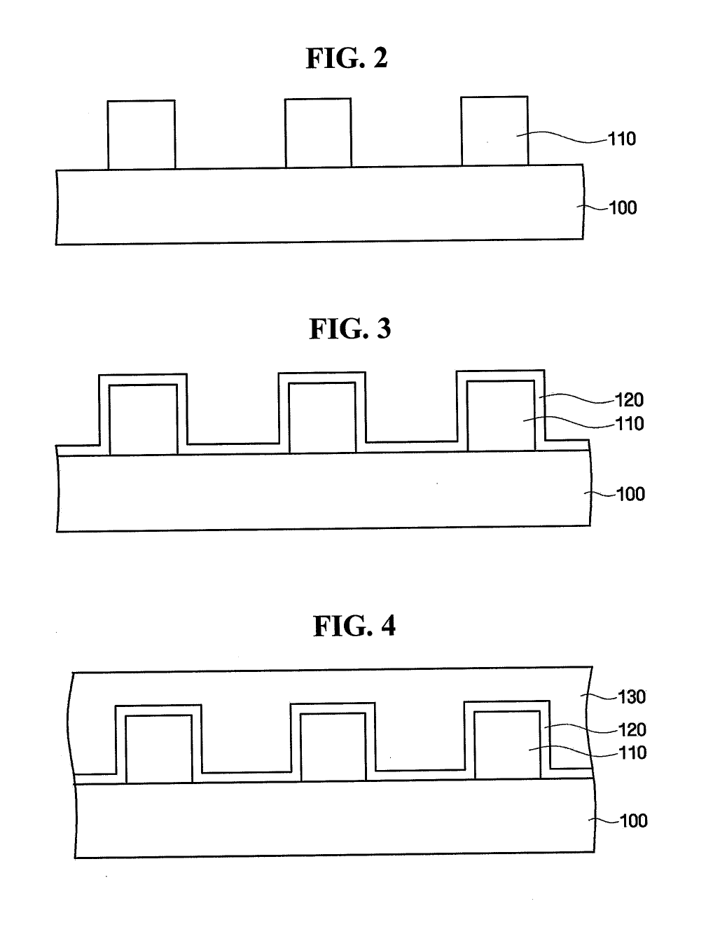

FIG. 1 illustrates a flowchart of a method of forming fine patterns of a semiconductor device according to an embodiment. FIGS. 2 through 7 illustrate cross-sectional views of stages in the method of forming fine patterns of a semiconductor device according to an embodiment.

Referring first to FIG. 1, a plurality of first photoresist layer patterns may be formed on a to-be-patterned or patternable layer (S100). Referring to FIG. 2, a first photoresist layer (not shown) may be coated on a patternable layer 100; and a patterning process may be performed, thereby forming a plurality of first photoresist layer patterns 110.

For example, a first photoresist layer (not shown) may be coated on the patternable layer 100 by a coating method followed by a pre-baking process. Then, a patterning process including sequential steps of exposure and development may be performed on the first photoresist layer, thereby forming the plurality of first photoresist layer patterns 110. The patternable layer 100 may include an underlying material from which fine patterns are to be made; and first photoresist layer patterns 110 may form even-numbered (e.g., (2n)th) column etch masks to be used in forming even-numbered column patterns among the fine patterns of the underlying material.

Next, referring to FIG. 1, an interfacial layer may be formed on the patternable layer and the plurality of first photoresist layer patterns (S110). Referring to FIG. 3, the interfacial layer 120 may be conformally formed on the patternable layer 100 and the plurality of first photoresist layer patterns 110.

For example, the interfacial layer 120 including at least one of a silicon film, an oxide film, a nitride film, a metal film, and combinations thereof, may be conformally formed on the patternable layer 100 and the plurality of first photoresist layer patterns 110 using ALD (Atomic Layer Deposition) or LTO (Low Temperature Oxide) Deposition. The interfacial layer 120 may prevent the first photoresist layer patterns 110 from being etched together with a planarization layer pattern (135 of FIG. 6) to be formed in a subsequent process. For example, the interfacial layer 120 may be an anti-reactive layer.

The interfacial layer 120 may have a thickness of about 5 to about 50 Å. Maintaining the thickness of the interfacial layer 120 at about 5 Å or greater may help ensure that the interfacial layer 120 properly functions as an anti-reactive layer. Maintaining the thickness of the interfacial layer 120 at about 50 Å or less may help ensure that the interfacial layer 120 is able to be etched efficiently in a subsequent stage in which fine patterns are to be formed on the patternable layer 100.

Referring again to FIG. 1, a planarization layer may be formed on the interfacial layer (S120). Referring to FIG. 4, the planarization layer 130 including an organic material may be formed on the interfacial layer 120. In an implementation, the planarization layer 130 may be an organic planarization layer including, e.g., SOH, SO, and/or NFC.

As shown in FIG. 4, the planarization layer 130 may be formed such that a height from a top surface of the patternable layer 100 to a top surface of the planarization layer 130 is greater than a height from the top surface of the patternable layer 100 to a top surface of portions of the interfacial layer 120 on the first photoresist layer patterns 110. The planarization layer 130 may be etched to then be used as an odd-numbered (e.g., (2n+1)th) column etch mask (135 of FIG. 6) in a subsequent process. Thus, the planarization layer 130 may form an odd-numbered column etch mask layer.

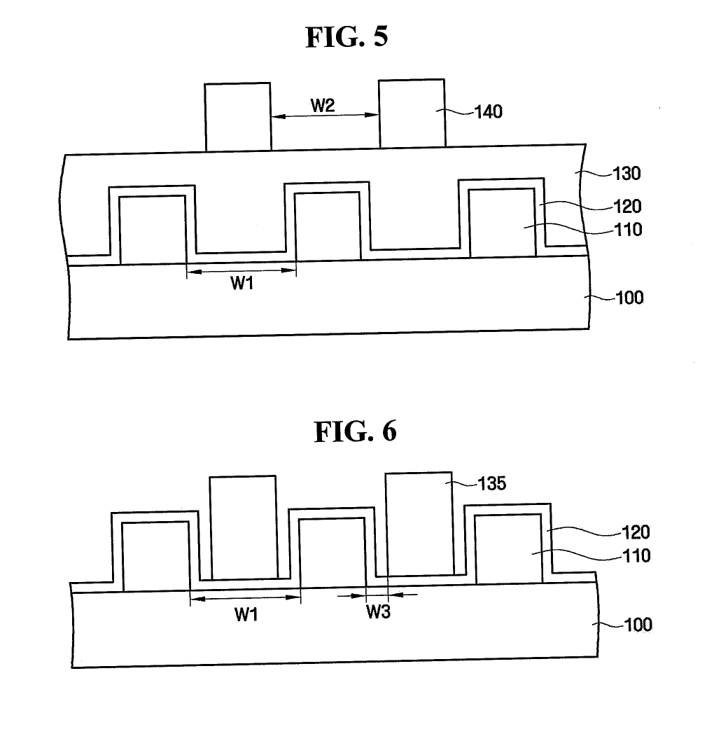

Referring again to FIG. 1, a plurality of second photoresist layer patterns may be formed on the planarization layer (S130). Referring to FIG. 5, a second photoresist layer (not shown) may be coated on the planarization layer 130 and patterned, thereby forming the plurality of second photoresist layer patterns 140.

For example, the second photoresist layer may be coated on the planarization layer 130 by a coating method, followed by a pre-baking process. Thereafter, a patterning process including, e.g., sequential steps of exposure and development, may be performed on the second photoresist layer, thereby forming the plurality of second photoresist layer patterns 140. The second photoresist layer patterns 140 may form auxiliary masks to be used in patterning the odd-numbered column etch mask (135 of FIG. 6).

In an implementation, an interval W1 between adjacent first photoresist layer patterns 110 may be about equal to an interval W2 between adjacent second photoresist layer patterns 140. The second photoresist layer patterns 140 may be formed between each of the first photoresist layer patterns 110 so as not to overlap the first photoresist layer patterns 110, as shown in FIG. 5.

Referring again to FIG. 1, a plurality of planarization layer patterns may be formed using the plurality of second photoresist layer patterns (S140). Referring to FIGS. 5 and 6, the planarization layer 130 may be etched using the plurality of second photoresist layer patterns 140 as etch masks, thereby forming the plurality of planarization layer patterns 135.

As described above, the planarization layer patterns 135 may form odd-numbered (e.g., (2n+1)th) column etch masks for patterning odd-numbered column patterns among fine patterns of the to patternable layer 100 (as an underlying material).

Referring to FIG. 6, in an implementation, an interval W3 between one of the planarization layer patterns 135 and an adjacent first photoresist layer pattern 110 may be smaller than the interval W1 between the adjacent first photoresist layer patterns 110 and/or the interval W2 between the adjacent second photoresist layer patterns 140.

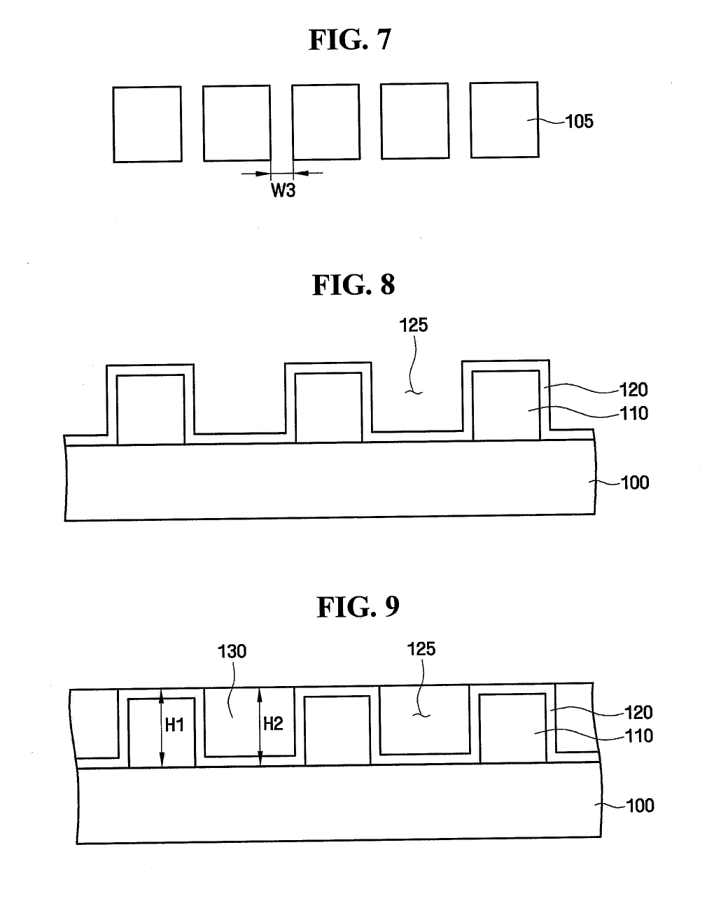

Referring again to FIG. 1, a plurality of layer patterns may be formed using the plurality of planarization layer patterns and the plurality of first photoresist layer patterns (S150). Referring to FIGS. 6 and 7, the patternable layer 100 may be etched using the plurality of planarization layer patterns 135 and the plurality of first photoresist layer patterns 110 as etch masks, thereby forming the layer patterns 105.

In an implementation, an interval W3 between adjacent layer patterns 105 may be about equal to the interval W3 between the planarization layer pattern 135 and the adjacent photoresist layer patterns 110. For example, in the method of forming fine patterns of a semiconductor device according to the present embodiments, finer patterns of a semiconductor device with higher reliability may be formed, compared to a conventional fine pattern forming method in which the first and second photoresist patterns 110 and 140 are independently formed.

Next, a method of forming fine patterns of a semiconductor device according to another embodiment will be described with reference to FIGS. 8 and 9.

FIGS. 8 and 9 illustrate cross-sectional views of stages in a method of forming fine patterns of a semiconductor device according to another embodiment. In the following description, the method of forming fine patterns of a semiconductor device according to the present embodiment will be described with reference to FIGS. 8 and 9, which may possess similar features to the previous embodiment and repetitive description will be omitted.

Referring first to FIG. 8, a cavity 125 having a bottom and side walls may be formed. The bottom may be formed by a patternable layer 100 or underlying material; and the side walls may be formed by first photoresist layer patterns 110 or even-numbered column etch masks. Then, an interfacial or anti-reactive layer 120 may be formed within the cavity 125 and on surfaces of the first photoresist layer patterns 110. As described above, the patternable layer 100 may be an underlying material, the first photoresist layer patterns 110 may form even-numbered (e.g., (2n)th) etch masks, and the interfacial layer 120 may be an anti-reactive layer.

Next, referring to FIG. 9, the cavity 125 having the interfacial layer 120 formed therein may be filled with the planarization layer 130. In the method according to the present embodiment, a height H2 from a top surface of the patternable layer 100 (i.e., the bottom of the cavity) to a top surface of the planarization layer 130 (i.e., the top surface of the even-numbered column etch masks) may be about equal to a height H1 from the top surface of the patternable layer 100 (i.e., the bottom of the cavity) to a top surface of portions of the interfacial or anti-reactive layer 120 on the first photoresist layer patterns 110. Like in the previous embodiment, the planarization layer 130 may form an odd-numbered (e.g., (2n+1)th) column etch mask layer; and planarization layer patterns 135 to be formed later may form odd-numbered (e.g., (2n+1)th) column etch masks.

Other aspects of the method may be substantially the same as those of the previous embodiment, and repeated detailed descriptions thereof will be omitted.

The embodiments provide a method of forming fine patterns of a semiconductor device with increased reliability.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of forming fine patterns of a semiconductor device, the method comprising:
providing a patternable layer;
forming a plurality of first photoresist layer patterns on the patternable layer;
forming an interfacial layer on the patternable layer and the plurality of first photoresist layer patterns;
forming a planarization layer on the interfacial layer;
forming a plurality of second photoresist layer patterns on the planarization layer;
forming a plurality of planarization layer patterns using the plurality of second photoresist layer patterns; and
forming a plurality of layer patterns using the plurality of planarization layer patterns and the plurality of first photoresist layer patterns.

2. The method as claimed in claim 1, wherein forming the interfacial layer includes conformally forming the interfacial layer on the patternable layer and the plurality of first photoresist layer patterns.

3. The method as claimed in claim 2, wherein conformally forming the interfacial layer includes ALD (Atomic Layer Deposition) or LTO (Low Temperature Oxide) deposition.

4. The method as claimed in claim 2, wherein the interfacial layer has a thickness of about 5 to about 50 Å.

5. The method as claimed in claim 1, wherein the interfacial layer includes at least one of a silicon film, an oxide film, a nitride film, a metal film, and combinations thereof.

6. The method as claimed in claim 1, wherein the planarization layer includes an organic material.

7. The method as claimed in claim 6, wherein the organic material includes at least one of SOH, SO, and NFC.

8. The method as claimed in claim 1, wherein forming the planarization layer on the interfacial layer includes forming the planarization layer such that a height from a top surface of the patternable layer to a top surface of the planarization layer is greater than a height from the top surface of the patternable layer to a top surface of portions of the interfacial layer on the first photoresist layer patterns.

9. The method as claimed in claim 1, wherein an interval between adjacent first photoresist layer patterns is about equal to an interval between adjacent second photoresist layer patterns.

10. The method as claimed in claim 9, wherein an interval between one of the planarization layer patterns and an adjacent first photoresist layer pattern is smaller than the interval between the adjacent first photoresist layer patterns or smaller than the interval between the adjacent second photoresist layer patterns.

11. The method as claimed in claim 1, wherein forming the plurality of planarization layer patterns using the plurality of second photoresist layer patterns includes etching the planarization layer using the plurality of second photoresist layer patterns as etch masks.

12. The method as claimed in claim 1, wherein forming the plurality of layer patterns using the plurality of planarization layer patterns and the plurality of first photoresist layer patterns includes etching the patternable layer using the plurality of planarization layer patterns and the plurality of first photoresist layer patterns as etch masks.

13. A method of forming fine patterns of a semiconductor device, the method comprising:
forming a cavity having a bottom and side walls such that the bottom is formed by an underlying material and the side walls are formed by even-numbered column etch masks;
forming an anti-reactive layer in the cavity and on surfaces of the even-numbered column etch masks;
filling the cavity having the anti-reactive layer therein with an odd-numbered column etch mask layer;
forming auxiliary masks on the odd-numbered column etch mask layer;
forming odd-numbered column etch masks by etching the odd-numbered column etch mask layer using the auxiliary masks; and
etching the underlying material using the even- and odd-numbered etch masks.

14. The method as claimed in claim 13, wherein the anti-reactive layer prevents the even-numbered column etch masks from being etched during forming of the odd-numbered etch masks.

15. The method as claimed in claim 13, wherein forming the anti-reactive layer includes conformally forming the anti-reactive layer in the cavity and on the surfaces of the even-numbered column etch masks.

16. The method as claimed in claim 15, wherein the anti-reactive layer has a thickness of about 5 to about 50 Å.

17. The method as claimed in claim 13, wherein the anti-reactive layer includes at least one of a silicon film, an oxide film, a nitride film, a metal film, and combinations thereof.

18. The method as claimed in claim 13, wherein the odd-numbered etch masks include an organic material, the organic material including at least one of SOH, SO, and NFC.

19. The method as claimed in claim 13, wherein filling the cavity with an odd-numbered column etch mask layer includes forming the odd-numbered column etch mask layer such that a height from the bottom of the cavity to a top surface of the odd-numbered column etch mask layer is about equal to a height from the bottom of the cavity to a top surface of portions of the anti-reactive layer on the even-numbered column etch masks.

20. A method for forming fine patterns of a semiconductor device, the method comprising:
providing a patternable layer;
forming a plurality of first photoresist layer patterns on the patternable layer;
conformally forming an interfacial layer having a thickness of about 5 to about 50 Å on the patternable layer and on the plurality of first photoresist layer patterns using ALD (Atomic Layer Deposition) or LTO (Low Temperature Oxide) deposition;
forming a planarization layer on the interfacial layer such that the planarization layer includes an organic material including at least one of SOH, SO, and NFC;
forming a plurality of second photoresist layer patterns on the planarization layer;
forming a plurality of planarization layer patterns by etching the planarization layer using the plurality of second photoresist layer patterns as etch masks; and
forming a plurality of layer patterns by etching the patternable layer using the plurality of planarization layer patterns and the plurality of first photoresist layer patterns as etch masks.
